(19) United States
(12) Patent Application Publication
(10) Pub. No.: US 2023/0274941 A1
(43) Pub. Date: Aug. 31, 2023

(54) METHOD FOR MANUFACTURING SEMICONDUCTOR POWER DEVICE

(71) Applicant: SUZHOU ORIENTAL SEMICONDUCTOR CO., LTD., Jiangsu (CN)

(72) Inventors: Zhendong MAO, Jiangsu (CN); Zhenyi XU, Jiangsu (CN); Wei LIU, Jiangsu (CN); Lei LIU, Jiangsu (CN)

(21) Appl. No.: 18/016,200

(22) PCT Filed: Nov. 25, 2020
(86) PCT No.: PCT/CN2020/131291

§ 371 Date: Jan. 13, 2023

(30) Foreign Application Priority Data
Nov. 12, 2020 (CN) 202011263819.9

(51) Int. Cl. H01L 21/311; H01L 21/02; H01L 29/423

(52) U.S. Cl. CPC H01L 21/31111; H01L 21/02164; H01L 29/42364

(57) ABSTRACT

A method for manufacturing a semiconductor power device includes forming a first recess in an n-type substrate and forming, in the first recess, a field oxide layer and a shielded gate; etching the field oxide layer in a self-aligned manner by taking the n-type substrate and the shielded gate as self-aligned boundaries, to etch away the field oxide layer in an upper portion of the first recess and to form a second recess in the upper portion of the first recess and between the shielded gate and the n-type substrate; forming an insulating dielectric layer covering sidewalls of a second recess and the bottom of the second recess and not filling the second recess; forming a layer of photoresist filling the remaining second recess; and performing photolithography, to expose the first insulating dielectric layer located in the second recess and on sides close to an n-type substrate, and etching away the first insulating dielectric layer located in the second recess and on sides close to the n-type substrate.

The present application claims priority to Chinese Patent Application No. 202011263819.9 filed with the China National Intellectual Property Administration (CNIPA) on Nov. 12, 2020, the disclosure of which is incorporated herein by reference in its entirety.

### TECHNICAL FIELD

Embodiments of the present application relate to the technical field of semiconductor power devices, for example, a method for manufacturing a semiconductor power device.

### BACKGROUND

In the related art, a method for manufacturing a semiconductor power device includes the following steps: first, as shown in FIG. 1, a hard mask layer 11 is formed on a silicon substrate 10, the position of a recess is defined through the process of photolithography, and then the hard mask layer 11 and the silicon substrate 10 are etched to form the recess 12; next, as shown in FIG. 2, a first insulating dielectric layer 13 is formed in the recess, then a first polysilicon layer is deposited and etched back so that the first polysilicon layer located outside the recess is removed, the remaining first polysilicon layer after etching forms a shielded gate 14, then the first insulating dielectric layer 13 is etched in a self-aligned manner by taking the shielded gate 14 and the part of the silicon substrate on the sides of the recess 12 as self-aligned boundaries, and the first insulating dielectric layer in the upper portion of the recess is removed and the first insulating dielectric layer 13 located in the lower portion of the recess is retained; and next, as shown in FIG. 3, a second insulating dielectric layer 15 is formed, then a second polysilicon layer is deposited and etched back so that the second polysilicon layer located outside the recess is removed, and the remaining second polysilicon layer after etching forms a polysilicon gate 16. In the method for manufacturing a semiconductor power device according to the related art, the polysilicon gate 16 is insulated from the shielded gate 14 by the second insulating dielectric layer 15. Since the second insulating dielectric layer 15 also serves as a gate dielectric layer between the polysilicon gate 16 and the silicon substrate 10, the thickness of the second insulating dielectric layer 15 is relatively small, resulting in a relatively small gate-source capacitance of the semiconductor power device and a relatively great gate-source leakage of the semiconductor power device.

### SUMMARY

The present application provides a method for manufacturing a semiconductor power device to reduce the gate-source capacitance of the semiconductor power device and reduce the gate-source leakage of the semiconductor power device.

The present application provides a method for manufacturing a semiconductor power device. The method includes the steps below.

A first recess is formed in an n-type substrate and a field oxide layer and a shielded gate are formed in the first recess.

The field oxide layer is etched in a self-aligned manner by taking the n-type substrate and the shielded gate as self-aligned boundaries, to etch away the field oxide layer in the upper portion of the first recess and to form a second recess in the upper portion of the first recess and between the shielded gate and the n-type substrate.

A first insulating dielectric layer is formed. The first insulating dielectric layer covers sidewalls of the second recess and the bottom of the second recess.

A layer of photoresist is formed. The photoresist fills the second recess.

Photolithography is performed, to expose the first insulating dielectric layer located in the second recess and on sides close to the n-type substrate; then the first insulating dielectric layer located in the second recess and on sides close to the n-type substrate is etched away; and the first insulating dielectric layer located in the second recess and on sides close to the shielded gate is retained.

The photoresist is removed and a gate dielectric layer and a gate are formed in the second recess.

Optionally, the method for manufacturing a semiconductor power device according to the present application further includes the steps below.

A p-type body region is formed in the n-type substrate.

An n-type source region is formed in the p-type body region.

Optionally, in the method for manufacturing a semiconductor power device according to the present application, the first insulating dielectric layer is a silicon oxide layer.

Optionally, in the method for manufacturing a semiconductor power device according to the present application, the step in which the first insulating dielectric layer is formed includes the step below.

The process of sub-atmospheric chemical vapor deposition is used to form the first insulating dielectric layer.

Optionally, in the method for manufacturing a semiconductor power device according to the present application, the step in which the first insulating dielectric layer located in the second recess and on sides close to the n-type substrate is etched away includes the step below.

The process of wet etching is used to etch away the first insulating dielectric layer located in the second recess and on sides close to the n-type substrate.

Optionally, in the method for manufacturing a semiconductor power device according to the present application, the n-type substrate is a silicon substrate.

Optionally, in the method for manufacturing a semiconductor power device according to the present application, the thickness of the first insulating dielectric layer is greater than the thickness of the gate dielectric layer.

In the method for manufacturing a semiconductor power device according to the present application, the photoresist is formed on the first photoresist and serves as a mask to retain the first insulating dielectric layer located in the second recess and on sides close to the shielded gate. With this arrangement, the thickness of the first insulating dielectric layer is relatively great. When the gate is insulated from the shielded gate by the first insulating dielectric layer, the gate-source capacitance is reduced, the gate-source leakage is reduced, and the reliability of the semiconductor power device is enhanced.

### BRIEF DESCRIPTION OF DRAWINGS

FIGS. 1 to 3 are each a section view illustrating the main structure in the manufacturing process of a method for manufacturing a semiconductor power device according to the related art.

FIGS. 4 to 7 are each a section view illustrating the main structure in the manufacturing process of a method for manufacturing a semiconductor power device according to an embodiment of the present application.

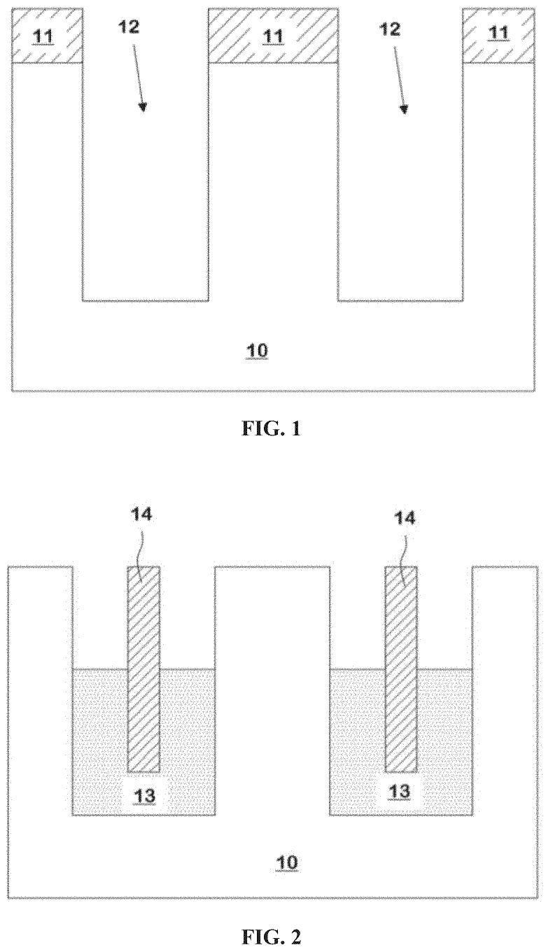

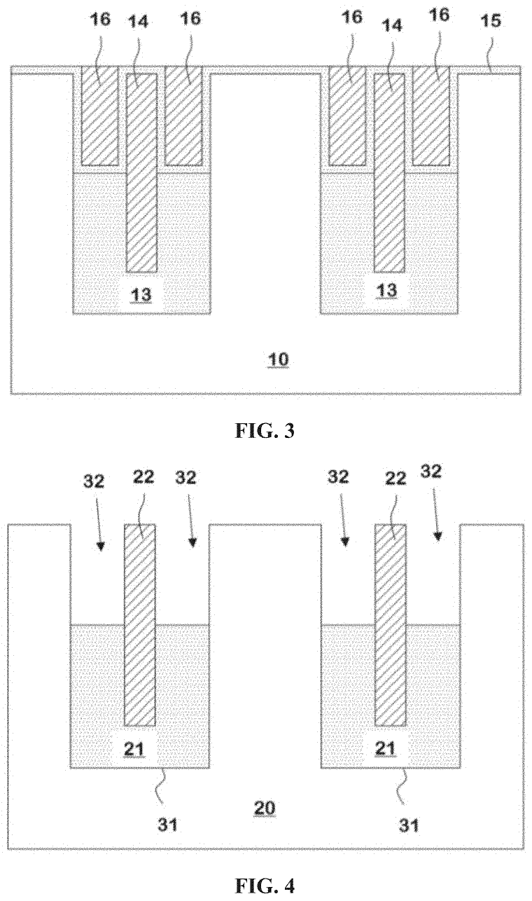

### DETAILED DESCRIPTION

Technical solutions of the present application are described completely hereinafter in conjunction with the drawings in embodiments of the present application. Apparently, the described embodiments are part, not all, of embodiments of the present disclosure. Meanwhile, to illustrate the embodiments of the present application clearly, in the schematic views illustrated in drawings of the description, thicknesses of layers and regions described in the present application are enlarged, and dimensions illustrated in the views do not represent the actual dimensions.

FIGS. 4 to 7 are each a section view illustrating the main structure in the manufacturing process of a method for manufacturing a semiconductor power device according to an embodiment of the present application.

First, as shown in FIG. 4, a first recess 31 is formed in a provided n-type substrate 20. The n-type substrate 20 is usually a silicon substrate. The number of first recesses 31 is determined based on the specification of the designed semiconductor power device. Embodiments of the present application merely illustrate two first recesses 31 exemplarily. Then according to a traditional process, a field oxide layer 21 and a shielded gate 22 are formed in the first recess 31. Moreover, the field oxide layer 21 is etched in a self-aligned manner by taking the n-type substrate 20 and the shielded gate 22 as self-aligned boundaries; the field oxide layer 21 in the upper portion of the first recess 31 is etched away; and a second recess 32 is formed in the upper portion of the first recess 31 and between the shielded gate 22 and the n-type substrate 20.

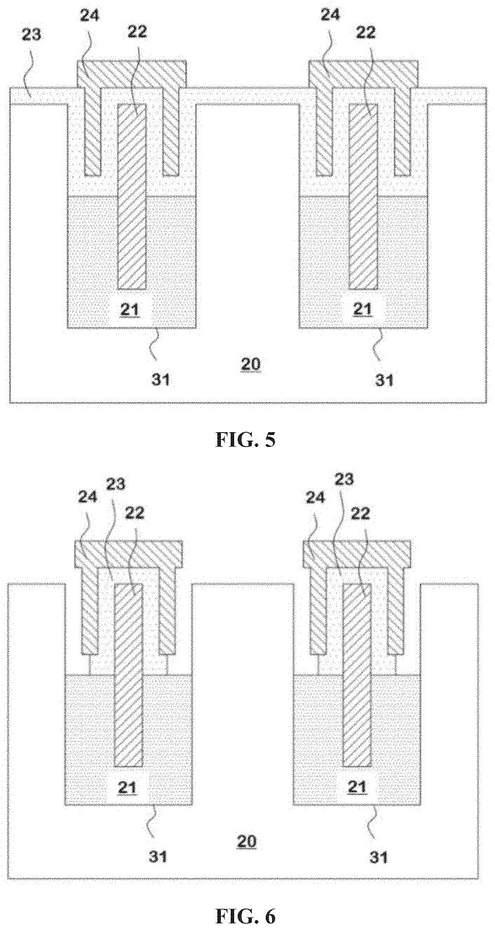

Next, as shown in FIG. 5, a first insulating dielectric layer 23 is formed. The first insulating dielectric layer 23 needs to cover sidewalls of the second recess and the bottom of the second recess. The first insulating dielectric layer 23 may not fill the second recess. The first insulating dielectric layer 23 is usually a silicon oxide layer and may be formed by using the process of sub-atmospheric chemical vapor deposition. Then a layer of photoresist 24 is formed. The photoresist 24 needs to fill the second recess. Then photolithography is performed and the first insulating dielectric layer 23 located in the second recess and on sides close to the n-type substrate 20 is exposed.

Next, as shown in FIG. 6, the first insulating dielectric layer located in the second recess and on sides close to the n-type substrate 20 is etched away and the first insulating dielectric layer 23 located in the second recess and on sides close to the shielded gate 22 is retained. When the first insulating dielectric layer 23 is etched in this step, the process of wet etching may be used so that the etching of the first insulating dielectric layer 23 is not limited by the etch selectivity between silicon oxide and silicon.

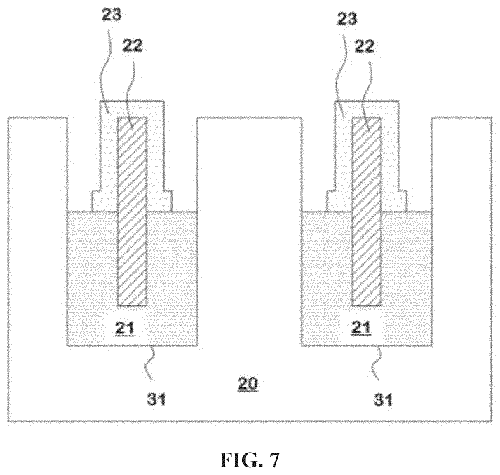

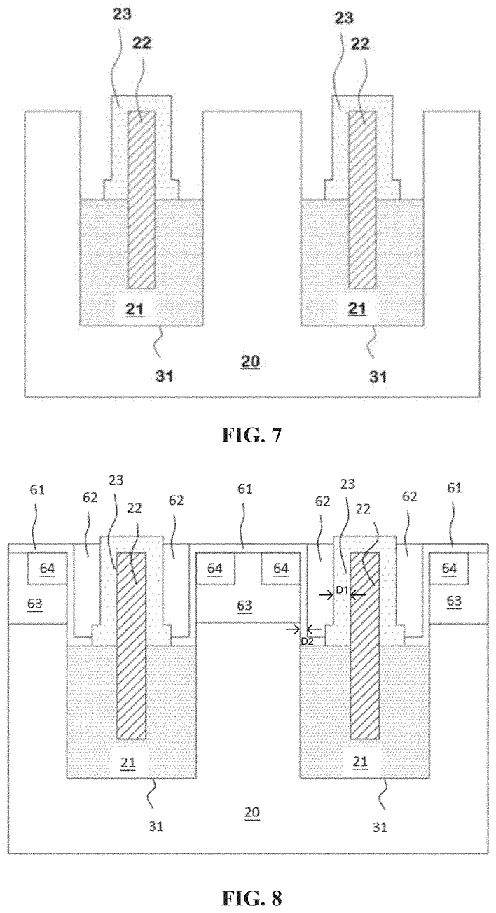

Next, as shown in FIG. 7, the photoresist is removed.

Finally, according to a traditional process, a gate dielectric layer and a gate are formed in the second recess. Moreover, a p-type body region is formed in the n-type substrate; an n-type source region is formed in the p-type body region; and then the semiconductor power device can be obtained after layers, for example, an insulating dielectric layer and a metal layer, are formed.

In the method for manufacturing a semiconductor power device according to the present application, the first insulating dielectric layer and the gate dielectric layer are formed through processes in two steps so that the thickness of the first insulating dielectric layer is greater than the thickness of the gate dielectric layer. Moreover, since the gate is insulated from the shielded gate by the first insulating dielectric layer, the arrangement of increasing the thickness of the first insulating dielectric layer helps reduce the gate-source capacitance, reduce the gate-source leakage, and enhance the reliability of the semiconductor power device.

1. A method for manufacturing a semiconductor power device, comprising:
forming a first recess in an n-type substrate and forming, in the first recess, a field oxide layer and a shielded gate;
etching the field oxide layer in a self-aligned manner by taking the n-type substrate and the shielded gate as self-aligned boundaries, to etch away the field oxide layer in an upper portion of the first recess and to form a second recess in the upper portion of the first recess and between the shielded gate and the n-type substrate;
forming an insulating dielectric layer in the second recess, wherein the insulating dielectric layer covers sidewalls of the second recess and a bottom of the second recess and does not fill the second recess;
forming a layer of photoresist on the insulating dielectric layer, wherein the photoresist fills the remaining second recess;
performing photolithography, to expose the insulating dielectric layer located in the second recess and on sides close to the n-type substrate, etching away the insulating dielectric layer located in the second recess and on the sides close to the n-type substrate, and retaining the insulating dielectric layer located in the second recess and on sides close to the shielded gate; and
removing the photoresist and forming, in the second recess, a gate dielectric layer and a gate.

2. The method of claim 1, further comprising:
forming a p-type body region in the n-type substrate; and
forming an n-type source region in the p-type body region.

3. The method of claim 1, wherein the insulating dielectric layer is a silicon oxide layer.

4. The method of claim 1, wherein forming the insulating dielectric layer in the second recess comprises:
using a process of sub-atmospheric chemical vapor deposition to form the insulating dielectric layer.

5. The method of claim 1, wherein etching away the insulating dielectric layer located in the second recess and on the sides close to the n-type substrate comprises:
using a process of wet etching to etch way the insulating dielectric layer located in the second recess and on the sides close to the n-type substrate.

6. The method of claim 1, wherein the n-type substrate is a silicon substrate.

7. The method of claim 1, wherein a thickness of the insulating dielectric layer between the shielded gate and the gate is greater than a thickness of the gate dielectric layer between the gate and the n-type substrate.

8. A semiconductor power device, wherein the semiconductor power device is manufactured by the method of claim 1.

9. The semiconductor power device of claim 8, wherein a thickness of the insulating dielectric layer between the shielded gate and the gate is greater than a thickness of the gate dielectric layer between the gate and the n-type substrate.
